(19) United States
(12) Patent Application Publication
(10) Pub. No.: US 2025/0038054 A1
(43) Pub. Date: Jan. 30, 2025

(54) TEST STRUCTURE AND METHOD FOR CALIBRATING GATE PARASITIC CAPACITANCE

(71) Applicant: Shanghai Huali Integrated Circuit Corporation, Shanghai (CN)

(72) Inventors: Qianqian ZHANG, Shanghai (CN); Zhiyong Han, Shanghai (CN); Hui Liu, Shanghai (CN)

(73) Assignee: Shanghai Huali Integrated Circuit Corporation, Shanghai (CN)

(21) Appl. No.: 18/744,489

(22) Filed: Jun. 14, 2024

(30) Foreign Application Priority Data
Jul. 27, 2023 (CN) 20231093463.2

(51) Int. Cl. H01L 21/66; G01R 27/26; H01L 27/092

(52) U.S. Cl. CPC H01L 22/34; G01R 27/2605; H01L 27/092

(57) ABSTRACT

This application provides a test structure and a method for calibrating gate parasitic capacitance. A first test structure can calibrate a dimension and thickness table related to a first metal layer in an ITF file. A second test structure is formed by an MOS structure after removing contact holes in source/drain regions, and this structure is used for calibrating gate dimension and thickness values in the ITF file. A third test structure is formed by the MOS structure after removing metal interconnect lines in source/drain regions, removing shallow doped source/drain regions composed of first conductive type lightly-doped regions, and this structure is used for calibrating tables related to capacitance Cco and Cf in the ITF file. A fourth test structure is an MOS structure, and its actual capacitance test result is compared with a simulation result to ensure that the gate parasitic capacitance conforms to the model simulation.

### CROSS-REFERENCES TO RELATED APPLICATIONS

This application claims priority to Chinese patent application No. CN202310934643.2, filed on Jul. 27, 2023 at CNIPA, and entitled “TEST STRUCTURE AND METHOD FOR CALIBRATING GATE PARASITIC CAPACITANCE”, the disclosure of which is incorporated herein by reference in entirety.

### TECHNICAL FIELD

This application relates to the field of semiconductor technology, and in particular to a test structure and a method for calibrating gate parasitic capacitance.

### BACKGROUND

With the development of integrated circuit manufacturing, the feature dimension is getting smaller, the widths of and spaces between lines are also getting smaller, and the delay of the parasitic effect is becoming more and more obvious. The requirement on the accuracy of the input file ITF of the backend parasitic capacitance and resistance extraction tool (such as StarRC) becomes higher and higher. How to effectively design the layout to obtain test data to calibrate the ITF is particularly crucial. Especially, the structure around the gate is complex, and the parasitic capacitance in the front-end-of-line metal interconnect structure is more complex than that in the back-end-of-line metal interconnect structure. The gate related capacitance includes the capacitance (Cgm) between the gate and the metal interconnect lines, the capacitance (Cco) between the gate and the contact holes, the capacitance (Cf) between the gate and the source/drain regions, and the device internal capacitance (including the channel capacitance, the capacitance of the overlapped region between the shallow doped source region or shallow doped drain region and the gate structure, and the junction capacitance), where Cco and Cf affect each other and are not easy to separate. For example, when the space between the contact holes and the space between the contact holes and the gate change, Cco is affected, the surface regions where the source/drain regions and the gate interact will also change, and thus Cf is affected. In addition, the device internal capacitance is also difficult to separate from the parasitic capacitance Cco and Cf.

At present, there are many reports on the test structures for separating Cco and Cf. In these reports, the capacitance Cco+Cf is measured when there are contact holes in the source/drain regions of the test structures, and the capacitance Cf is measured when there are no contact holes in the source/drain regions, thus separating the capacitance Cco and Cf. However, this type of test methods does not consider the influence of contact hole arrangement on the capacitance Cf, which deviates from the actual results. Therefore, it is particularly important to use an effective calibration method to separately calibrate the parasitic parameters related to the gate parasitic capacitance and improve the accuracy of ITF.

### BRIEF SUMMARY

The present application provides a test structure and a method for calibrating gate parasitic capacitance, which are used for solving the problem that the parasitic parameters related to the gate parasitic capacitance in the existing technology deviate from the actual results.

This application provides a test structure, at least including:
an MOS structure, the MOS structure including: a silicon substrate, a second conductive type lightly-doped well region located on the silicon substrate, and first conductive type heavily-doped source/drain regions, a shallow trench isolation region and a second conductive type heavily-doped body leading-out region sequentially spaced apart from each other and located on a shallow region of the second conductive type lightly-doped well region; a gate located on the second conductive type lightly-doped well region between the first conductive type heavily-doped source/drain regions; shallow doped source/drain regions composed of first conductive type lightly-doped regions, located in the second conductive type lightly-doped regions on two sides of the gate and overlapped with the first conductive type heavily-doped source/drain regions; contact holes connected respectively from the first conductive type heavily-doped source/drain regions and the second conductive type heavily-doped body leading-out region; and first metal lines located on the contact holes;
the gate related capacitance of the MOS structure including parasitic capacitance and device internal capacitance Cin; the parasitic capacitance including: capacitance Cf between the gate and source/drain regions, capacitance Cco between the gate and the contact holes, and capacitance Cgm1 between the gate and the first metal lines; the device internal capacitance Cin including: channel capacitance Cgd between the gate and a well region, capacitance Cov of overlapped regions respectively between the shallow doped source/drain regions and the gate structure, and junction capacitance between the first conductive type heavily-doped source/drain regions and the second conductive type lightly-doped well region;
a first test structure including a plurality of intralayer capacitance test structures, an interlayer capacitance test structure, and an interlayer and intralayer test structure,
each intralayer capacitance test structure of the plurality of intralayer capacitance test structures being composed of metal lines belonging to the same layer, the widths of the metal lines being the same, the spaces between adjacent metal lines being the same; the widths of the metal lines and the spaces between adjacent metal lines of the plurality of intralayer capacitance test structures being respectively different from each other, the metal lines of the plurality of intralayer capacitance test structures belonging to different layers, each intralayer capacitance test structure being used for measuring the capacitance between the metal lines of the same layer;
the interlayer capacitance test structure being composed of the intralayer capacitance test structures belonging to the different layers, and being used for measuring the capacitance between the metal lines of the different layers;
the interlayer and intralayer test structure being composed of the intralayer capacitance test structures and the interlayer capacitance test structure, and being used for measuring the total of the capacitance between the metal lines of the same layer and the capacitance between the metal lines of the different layers;
a second test structure formed by the MOS structure after removing the contact holes and used for measuring the capacitance Cgm1 between the gate and the first metal lines; the second test structure including different test structures with the same channel length, the same surrounding environment and different channel widths, and being used for calculating a difference in the capacitance Cgm1 between each other;
a third test structure formed by the MOS structure after removing the first metal lines on the first conductive type heavily-doped source/drain regions, removing the shallow doped source/drain regions composed of the first conductive type lightly-doped regions, and sequentially replacing the second conductive type lightly-doped well region and the second conductive type heavily-doped body leading-out region with a first conductive type lightly-doped well region and a first conductive type heavily-doped body leading-out region; the third test structure including different test structures with the same channel width, the same surrounding environment and different channel lengths, and being used for measuring a difference in the channel capacitance Cgd between each other; the third test structure further including different test structures with different spaces between the contact holes and different spaces between the contact holes and the gate;
a fourth test structure formed by the MOS structure, the fourth test structure including different test structures with the same channel length, the same surrounding environment and different channel widths, and being used for measuring the total difference Ctotal in the capacitance Cf between the gate and the source/drain regions, the capacitance Cco between the gate and the contact holes, the capacitance Cgm1 between the gate and the first metal lines, and the device internal capacitance Cin.

Exemplarily, the MOS structure is an N-type device, the first conductive type is N-type, and the second conductive type is P-type.

Exemplarily, the MOS structure is a P-type device, the first conductive type is P-type, and the second conductive type is N-type.

Exemplarily, the capacitance of the third test structure is the total of the capacitance Cf between the gate and the source/drain regions, the capacitance Cco between the gate and the contact holes, and the channel capacitance Cgd between the gate and the well region.

This application further provides a method for calibrating parasitic capacitance, at least including:
step 1: providing a first test structure, the first test structure including a plurality of intralayer capacitance test structures, an interlayer capacitance test structure, and an interlayer and intralayer test structure,
each intralayer capacitance test structure of the plurality of intralayer capacitance test structures being composed of metal lines belonging to the same layer, the widths of the metal lines being the same, the spaces between adjacent metal lines being the same; the widths of the metal lines and the spaces between adjacent metal lines of the plurality of intralayer capacitance test structures being respectively different from each other, the metal lines of the plurality of intralayer capacitance test structures belonging to different layers;
the interlayer capacitance test structure being composed of the intralayer capacitance test structures belonging to the different layers;
the interlayer and intralayer test structure being composed of the intralayer capacitance test structures and the interlayer capacitance test structure;
respectively measuring the capacitance between the metal lines of the same layer in the intralayer capacitance test structures, the capacitance between the metal lines of the different layers in the interlayer capacitance test structure, and the total of the capacitance between the metal lines of the same layer and the capacitance between the metal lines of the different layers in the interlayer and intralayer test structure, measurement results of the capacitance and the total of the capacitance being actual capacitance values;
respectively measuring the actual widths and thicknesses of the metal lines and the spaces between adjacent metal lines in the first test structure, and writing measurement values into an ITF file, the ITF file being an input file of a backend parasitic capacitance and resistance extraction tool;
comparing the actual capacitance values with respective simulation values, and adjusting numerical values in an ETCH table and a thickness table in the ITF file to make simulation results consistent with actual measurement results;
step 2: providing an MOS structure, the MOS structure including: a silicon substrate, a second conductive type lightly-doped well region located on the silicon substrate, and first conductive type heavily-doped source/drain regions, a shallow trench isolation region and a second conductive type heavily-doped body leading-out region sequentially spaced apart from each other and located on a shallow region of the second conductive type lightly-doped well region; a gate located on the second conductive type lightly-doped well region between the first conductive type heavily-doped source/drain regions; shallow doped source/drain regions composed of first conductive type lightly-doped regions, located in the second conductive type lightly-doped regions on two sides of the gate and overlapped with the first conductive type heavily-doped source/drain regions; contact holes connected respectively from the first conductive type heavily-doped source/drain regions and the second conductive type heavily-doped body leading-out region; and first metal lines located on the contact holes;
the gate related capacitance of the MOS structure including parasitic capacitance and device internal capacitance Cin; the parasitic capacitance including: capacitance Cf between the gate and source/drain regions, capacitance Cco between the gate and the contact holes, and capacitance Cgm1 between the gate and the first metal lines; the device internal capacitance Cin including: channel capacitance Cgd between the gate and a well region, capacitance Cov of overlapped regions respectively between the shallow doped source/drain regions and the gate structure, and junction capacitance between the first conductive type heavily-doped source/drain regions and the second conductive type lightly-doped well region;
providing a second test structure, the second test structure being formed by the MOS structure after removing the contact holes; the second test structure including different test structures with the same channel length, the same surrounding environment and different channel widths; measuring the capacitance Cgm1 between the gate and the first metal lines of the different test structures, and calculating a difference in the capacitance Cgm1 between each other;
performing simulation on the capacitance Cgm1 between the gate and the first metal lines of the different test structures by using the backend parasitic capacitance and resistance extraction tool to obtain simulation values, and calculating a difference in the simulation capacitance Cgm1 between the different test structures;
comparing the difference in the simulation capacitance Cgm1 with the measured difference in the capacitance Cgm1 between the different test structures, and adjusting the dimension of the gate in the ITF file to make simulation results consistent with actual measurement results;
step 3: providing a third test structure, the third test structure being formed by the MOS structure after removing the first metal lines on the first conductive type heavily-doped source/drain regions, removing the shallow doped source/drain regions composed of the first conductive type lightly-doped regions, and sequentially replacing the second conductive type lightly-doped well region and the second conductive type heavily-doped body leading-out region with a first conductive type lightly-doped well region and a first conductive type heavily-doped body leading-out region; the third test structure including different test structures with the same channel width, the same surrounding environment and different channel lengths; measuring the channel capacitance Cgd of the different test structures, and calculating a difference in the capacitance Cgd between each other;
performing simulation on the channel capacitance Cgd of the different test structures by using the backend parasitic capacitance and resistance extraction tool to obtain simulation values, and calculating a difference in the simulation capacitance Cgd between the different test structures;
comparing the difference in the simulation capacitance Cgd with the measured difference in the capacitance Cgd between the different test structures, and adjusting the dimension of the gate in the ITF file to make simulation results consistent with actual measurement results;
the third test structure further including different test structures with different spaces between the contact holes and different spaces between the contact holes and the gate; measuring capacitance values of the different test structures; determining capacitance Cco related parameters in the ITF file, and then calibrating a capacitance Cf table in the ITF file according to the actually measured capacitance values;
step 4: providing a fourth test structure, the fourth test structure being formed by the MOS structure, the fourth test structure including different test structures with the same channel length, the same surrounding environment and different channel widths; measuring the capacitance Cf between the gate and the source/drain regions, the capacitance Cco between the gate and the contact holes, and the capacitance Cgm1 between the gate and the first metal lines of the different test structures, and the device internal capacitance Cin, and calculating the total difference Ctotal in the capacitance;
performing simulation on the total difference Ctotal in the capacitance of the different test structures by using the backend parasitic capacitance and resistance extraction tool to obtain simulation values, and comparing the simulation values with actual measurement values to adjust the Cf table in the ITF file.

Exemplarily, in step 1, an electron transmission microscope is used for respectively measuring the widths of and spaces between the metal lines, and a WAT is used for measuring the capacitance between the metal lines of the same layer in the intralayer capacitance test structures, the capacitance between the metal lines of the different layers in the interlayer capacitance test structure, and the total of the capacitance between the metal lines of the same layer and the capacitance between the metal lines of the different layers in the interlayer and intralayer test structure.

Exemplarily, in step 1 to step 4, the backend parasitic capacitance and resistance extraction tool is StarRC.

Exemplarily, in step 2, a WAT is used for respectively measuring the capacitance Cgm1 between the gate and the first metal lines of the different test structures.

Exemplarily, in step 3, a WAT is used for respectively measuring the channel capacitance Cgd of the different test structures.

Exemplarily, in step 4, a WAT is used for respectively measuring the capacitance Cf between the gate and the source/drain regions, the capacitance Cco between the gate and the contact holes and the capacitance Cgm1 between the gate and the first metal lines of the different test structures, and the device internal capacitance Cin.

As described above, the test structure and the method for calibrating gate parasitic capacitance according to this application have the following beneficial effects: the method according to this application can respectively calibrate the capacitance Cgm between and the gate and the metal interconnect lines, the capacitance Cco between the gate and the contact holes and the capacitance Cf between the gate and the source/drain regions, can make sure that the parasitic capacitance complies with the device internal capacitance involved in the model, and can effectively improve the accuracy of the parasitic capacitance extraction tool.

### BRIEF DESCRIPTION OF THE DRAWINGS

FIG. 1 illustrates a flowchart of a method for calibrating parasitic capacitance according to this application.

FIG. 2 illustrates a schematic diagram of a sectional structure of an MOS structure according to this application.

FIG. 3a illustrates a top schematic diagram of intralayer capacitance test structures in a first test structure according to this application.

FIG. 3b illustrates a top schematic diagram of an interlayer capacitance test structure in a first test structure according to this application.

FIG. 3c illustrates a top schematic diagram of an interlayer and intralayer capacitance test structures in a first test structure according to this application.

FIG. 4 illustrates a schematic diagram of a sectional structure of a second test structure according to this application.

FIG. 5a illustrates a schematic diagram of a layout of a test structure with a channel width of W1 in a second test structure according to this application.

FIG. 5b illustrates a schematic diagram of a layout of a test structure with a channel width of W2 in a second test structure according to this application.

FIG. 5c illustrates a schematic diagram of a layout corresponding to a difference in capacitance between the test structure in FIG. 5a and the test structure in FIG. 5b according to this application.

FIG. 6 illustrates a schematic diagram of a sectional structure of a third test structure according to this application.

FIG. 7a illustrates a schematic diagram of a layout of a test structure with a channel length of L1 in a third test structure according to this application.

FIG. 7b illustrates a schematic diagram of a layout of a test structure with a channel length of L2 in a third test structure according to this application.

FIG. 7c illustrates a schematic diagram of a layout corresponding to a difference in capacitance between the test structure in FIG. 7a and the test structure in FIG. 7b according to this application.

FIG. 8 illustrates a schematic diagram of a layout of spaces between different contact holes and spaces between contact holes and a gate in a third test structure according to this application.

FIG. 9a illustrates a schematic diagram of a layout of a structure of four contact holes in a fourth test structure according to this application.

FIG. 9b illustrates a schematic diagram of a layout of a structure of two contact holes in a fourth test structure according to this application.

FIG. 9c illustrates a schematic diagram of a layout corresponding to a difference in capacitance between the test structure in FIG. 9a and the test structure in FIG. 9b according to this application.

### DETAILED DESCRIPTION OF THE EMBODIMENTS

The embodiments of this application will be described below through specific examples. Those skilled in the art can easily understand other advantages and effects of this application from the content disclosed in this description. This application may also be implemented or applied through other different specific embodiments. The details in this description may be modified or changed based on different perspectives and applications without departing from the spirit of this application.

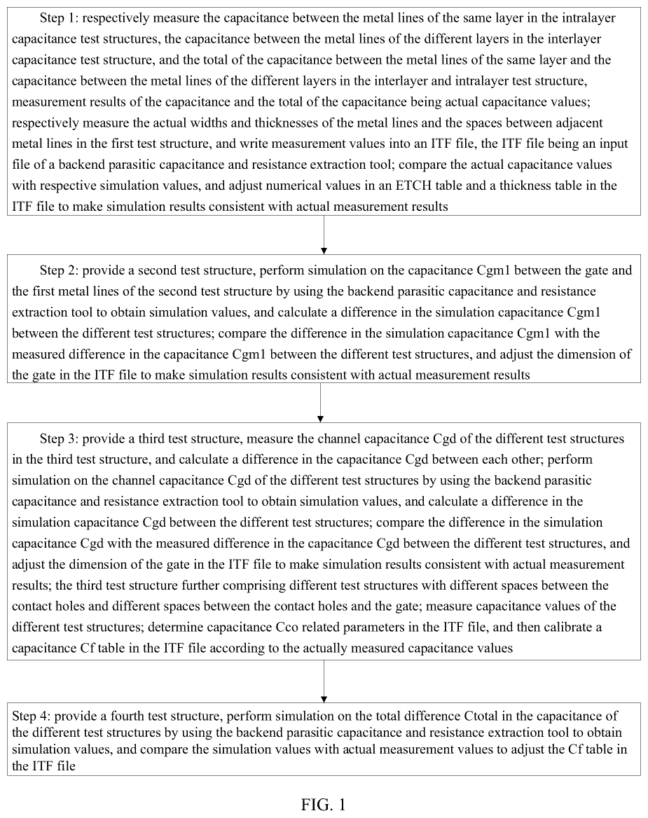

Please refer to FIG. 1 to FIG. 9c. It should be noted that the drawings provided in the embodiments only schematically describe the basic concept of this application, only illustrate the components related to this application, and are not drawn according to the actual number, shape and size of the components during implementation. The type, number and scale of each component during actual implementation may be freely changed, and the layout of the component may be more complex.

This application provides a test structure, at least includes an MOS structure, a first test structure, a second test structure, a third test structure, and a fourth test structure.

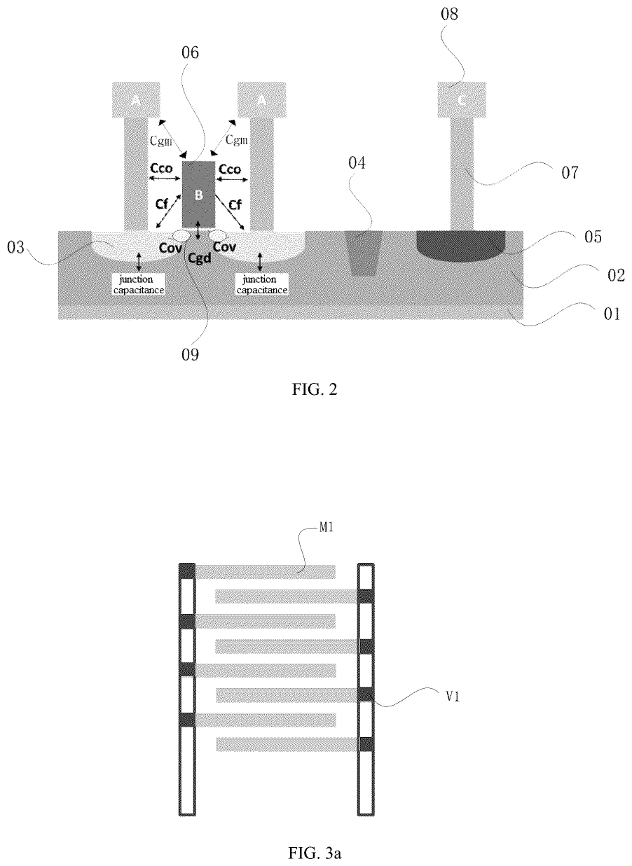

Referring to FIG. 2 which illustrates a schematic diagram of a sectional structure of an MOS structure according to this application, the MOS structure includes: a silicon substrate 01, a second conductive type lightly-doped well region 02 located on the silicon substrate 01, and first conductive type heavily-doped source/drain regions 03 (a source region or drain region is marked with 03 in FIG. 2), a shallow trench isolation region 04 and a second conductive type heavily-doped body leading-out region 05 sequentially spaced apart from each other and located on a shallow region of the second conductive type lightly-doped well region 02; a gate 06 located on the second conductive type lightly-doped well region 02 between the first conductive type heavily-doped source/drain regions (between the source region and the drain region); shallow doped source/drain regions 09 composed of first conductive type lightly-doped regions, located in the second conductive type lightly-doped regions on two sides of the gate 06 and overlapped with the first conductive type heavily-doped source/drain regions 03; contact holes 07 connected respectively from the first conductive type heavily-doped source/drain regions 03 and the second conductive type heavily-doped body leading-out region 05; and first metal lines 08 (i.e., first-layer metal lines) located on the contact holes 07.

The gate related capacitance of the MOS structure includes parasitic capacitance and device internal capacitance Cin. The parasitic capacitance includes capacitance Cf between the gate and source/drain regions, capacitance Cco between the gate and the contact holes, and capacitance Cgm1 between the gate and the first metal lines. The device internal capacitance Cin includes channel capacitance Cgd between the gate and a well region, capacitance Cov of overlapped regions respectively between the shallow doped source/drain regions and the gate structure, and junction capacitance between the first conductive type heavily-doped source/drain regions and the second conductive type lightly-doped well region.

The first test structure includes a plurality of intralayer capacitance test structures, an interlayer capacitance test structure, and an interlayer and intralayer test structure.

Each intralayer capacitance test structure of the plurality of intralayer capacitance test structures is composed of metal lines belonging to the same layer. The widths of the metal lines are the same. The spaces between adjacent metal lines are the same. The widths of the metal lines and the spaces between adjacent metal lines of the plurality of intralayer capacitance test structures are respectively different from each other. The metal lines of the plurality of intralayer capacitance test structures belong to different layers. Each intralayer capacitance test structure is used for measuring the capacitance between the metal lines of the same layer.

The interlayer capacitance test structure is composed of the intralayer capacitance test structures belonging to the different layers, and is used for measuring the capacitance between the metal lines of the different layers.

The interlayer and intralayer test structure is composed of the intralayer capacitance test structures and the interlayer capacitance test structure, and is used for measuring the total of the capacitance between the metal lines of the same layer and the capacitance between the metal lines of the different layers.

The second test structure is formed by the MOS structure after removing the contact holes and used for measuring the capacitance Cgm1 between the gate and the first metal lines. The second test structure includes different test structures with the same channel length, the same surrounding environment and different channel widths, and is used for calculating a difference in the capacitance Cgm1 between each other.

The third test structure is formed by the MOS structure after removing the first metal lines on the first conductive type heavily-doped source/drain regions, removing the shallow doped source/drain regions composed of the first conductive type lightly-doped regions, and sequentially replacing the second conductive type lightly-doped well region and the second conductive type heavily-doped body leading-out region with a first conductive type lightly-doped well region and a first conductive type heavily-doped body leading-out region. The third test structure includes different test structures with the same channel width, the same surrounding environment and different channel lengths, and is used for measuring a difference in the channel capacitance Cgd between each other. The third test structure further includes different test structures with different spaces between the contact holes and different spaces between the contact holes and the gate.

The fourth test structure is formed by the MOS structure. The fourth test structure includes different test structures with the same channel length, the same surrounding environment and different channel widths, and is used for measuring the total difference Ctotal in the capacitance Cf between the gate and the source/drain regions, the capacitance Cco between the gate and the contact holes, the capacitance Cgm1 between the gate and the first metal lines, and the device internal capacitance Cin.

Further, in this application, the MOS structure is an N-type device, the first conductive type is N-type, and the second conductive type is P-type.

Further, in this application, the MOS structure is a P-type device, the first conductive type is P-type, and the second conductive type is N-type.

Further, in this application, the capacitance of the third test structure is the total of the capacitance Cf between the gate and the source/drain regions, the capacitance Cco between the gate and the contact holes, and the channel capacitance Cgd between the gate and the well region.

This application further provides a method for calibrating parasitic capacitance. Referring to FIG. 1 which illustrates a flowchart of a method for calibrating parasitic capacitance according to this application, the method at least includes the following steps:

In step 1, a first test structure is provided. The first test structure includes a plurality of intralayer capacitance test structures, an interlayer capacitance test structure, and an interlayer and intralayer test structure.

Each intralayer capacitance test structure of the plurality of intralayer capacitance test structures is composed of metal lines belonging to the same layer. The widths of the metal lines are the same. The spaces between adjacent metal lines are the same. The widths of the metal lines and the spaces between adjacent metal lines of the plurality of intralayer capacitance test structures are respectively different from each other. The metal lines of the plurality of intralayer capacitance test structures belong to different layers.

The interlayer capacitance test structure is composed of the intralayer capacitance test structures belonging to the different layers.

The interlayer and intralayer test structure is composed of the intralayer capacitance test structures and the interlayer capacitance test structure.

The capacitance between the metal lines of the same layer in the intralayer capacitance test structures, the capacitance between the metal lines of the different layers in the interlayer capacitance test structure, and the total of the capacitance between the metal lines of the same layer and the capacitance between the metal lines of the different layers in the interlayer and intralayer test structure are respectively measured. Measurement results of the capacitance and the total of the capacitance are actual capacitance values.

The actual widths and thicknesses of the metal lines and the spaces between adjacent metal lines in the first test structure are respectively measured. Measurement values are written into an ITF file. The ITF file is an input file of a backend parasitic capacitance and resistance extraction tool.

The actual capacitance values are compared with respective simulation values. Numerical values in an ETCH table and a thickness table in the ITF file are adjusted to make simulation results consistent with actual measurement results.

Further, in this application, in step 1, an electron transmission microscope is used for respectively measuring the widths of and spaces between the metal lines, and a WAT is used for measuring the capacitance between the metal lines of the same layer in the intralayer capacitance test structures, the capacitance between the metal lines of the different layers in the interlayer capacitance test structure, and the total of the capacitance between the metal lines of the same layer and the capacitance between the metal lines of the different layers in the interlayer and intralayer test structure.

Further, in this application, in step 1, the backend parasitic capacitance and resistance extraction tool is StarRC.

In step 2, an MOS structure is provided. The MOS structure includes: a silicon substrate, a second conductive type lightly-doped well region located on the silicon substrate, and first conductive type heavily-doped source/drain regions, a shallow trench isolation region and a second conductive type heavily-doped body leading-out region sequentially spaced apart from each other and located on a shallow region of the second conductive type lightly-doped well region; a gate located on the second conductive type lightly-doped well region between the first conductive type heavily-doped source/drain regions; shallow doped source/drain regions composed of first conductive type lightly-doped regions, located in the second conductive type lightly-doped regions on two sides of the gate and overlapped with the first conductive type heavily-doped source/drain regions; contact holes connected respectively from the first conductive type heavily-doped source/drain regions and the second conductive type heavily-doped body leading-out region; and first metal lines located on the contact holes.

The gate related capacitance of the MOS structure includes parasitic capacitance and device internal capacitance Cin. The parasitic capacitance includes capacitance Cf between the gate and source/drain regions, capacitance Cco between the gate and the contact holes, and capacitance Cgm1 between the gate and the first metal lines. The device internal capacitance Cin includes channel capacitance Cgd between the gate and a well region, capacitance Cov of overlapped regions respectively between the shallow doped source/drain regions and the gate structure, and junction capacitance between the first conductive type heavily-doped source/drain regions and the second conductive type lightly-doped well region.

A second test structure is provided. the second test structure is formed by the MOS structure after removing the contact holes. The second test structure includes different test structures with the same channel length, the same surrounding environment and different channel widths. The capacitance Cgm1 between the gate and the first metal lines of the different test structures is measured. A difference in the capacitance Cgm1 between each other is calculated.

Simulation is performed on the capacitance Cgm1 between the gate and the first metal lines of the different test structures by using the backend parasitic capacitance and resistance extraction tool to obtain simulation values. A difference in the simulation capacitance Cgm1 between the different test structures is calculated.

The difference in the simulation capacitance Cgm is compared with the measured difference in the capacitance Cgm1 between the different test structures. The dimension of the gate in the ITF file is adjusted to make simulation results consistent with actual measurement results.

Further, in this application, in step 2, a WAT is used for respectively measuring the capacitance Cgm1 between the gate and the first metal lines of the different test structures.

Further, in this application, in step 2, the backend parasitic capacitance and resistance extraction tool is StarRC.

In step 3, a third test structure is provided. The third test structure is formed by the MOS structure after removing the first metal lines on the first conductive type heavily-doped source/drain regions, removing the shallow doped source/drain regions composed of the first conductive type lightly-doped regions, and sequentially replacing the second conductive type lightly-doped well region and the second conductive type heavily-doped body leading-out region with a first conductive type lightly-doped well region and a first conductive type heavily-doped body leading-out region. The third test structure includes different test structures with the same channel width, the same surrounding environment and different channel lengths. The channel capacitance Cgd of the different test structures is measured. A difference in the capacitance Cgd between each other is calculated.

Simulation is performed on the channel capacitance Cgd of the different test structures by using the backend parasitic capacitance and resistance extraction tool to obtain simulation values. A difference in the simulation capacitance Cgd between the different test structures is calculated.

The difference in the simulation capacitance Cgd is compared with the measured difference in the capacitance Cgd between the different test structures. The dimension of the gate in the ITF file is adjusted to make simulation results consistent with actual measurement results.

The third test structure further includes different test structures with different spaces between the contact holes and different spaces between the contact holes and the gate. Capacitance values of the different test structures are measured. Capacitance Cco related parameters in the ITF file are determined. Then, a capacitance Cf table in the ITF file is calibrated according to the actually measured capacitance values.

Further, in this application, in step 3, a WAT is used for respectively measuring the channel capacitance Cgd of the different test structures.

Further, in this application, in step 3, the backend parasitic capacitance and resistance extraction tool is StarRC.

In step 4, a fourth test structure is provided. The fourth test structure is formed by the MOS structure. The fourth test structure includes different test structures with the same channel length, the same surrounding environment and different channel widths. The capacitance Cf between the gate and the source/drain regions, the capacitance Cco between the gate and the contact holes, and the capacitance Cgm between the gate and the first metal lines of the different test structures, and the device internal capacitance Cin are measured. The total difference Ctotal in the capacitance is calculated.

Simulation is performed on the total difference Ctotal in the capacitance of the different test structures by using the backend parasitic capacitance and resistance extraction tool to obtain simulation values. The simulation values are compared with actual measurement values to adjust the Cf table in the ITF file.

Further, in this application, in step 4, a WAT is used for respectively measuring the capacitance Cf between the gate and the source/drain regions, the capacitance Cco between the gate and the contact holes and the capacitance Cgm1 between the gate and the first metal lines of the different test structures, and the device internal capacitance Cin.

Further, in this application, in step 4, the backend parasitic capacitance and resistance extraction tool is StarRC.

### Embodiments

In this embodiment, calibration of 28HK gate parasitic capacitance is taken as an example, different test layouts are drawn by using virtuoso, a synopsis parasitic capacitance extraction tool StarRC is used for extracting parasitic capacitance, hspice is used for simulating parasitic capacitance and device internal capacitance, a WAT is used for testing capacitance, and a Transmission Electron Microscope (TEM) is used for measuring thickness and width.

### DESCRIPTION OF REFERENCE SIGNS

AA: active area;
S/D: source/drain region;
Gate: gate;
Fgate: part of gate in reactive area;
M1, M2, M3: RESPECTIVELY AND SEQUENTIALLY FIRST-LAYER METAL LINE (FIRST METAL LINE), SECOND-LAYER METAL LINE, AND THIRD-LAYER METAL LINE;
V1: VIA FOR CONNECTING M1 AND M2;
V2: VIA FOR CONNECTING M2 AND M3;
CT: CONTACT HOLE FOR CONNECTING SOURCE/DRAIN REGIONS WITH VIA OF M1, AND CONNECTING GATE WITH VIA OF M1;
CGM: CAPACITANCE BETWEEN GATE AND METAL INTERCONNECT LINE;
CGM1: CAPACITANCE BETWEEN GATE AND FIRST METAL LINE;
CCO: PARASITIC CAPACITANCE BETWEEN GATE AND CONTACT HOLE;
CF: PARASITIC CAPACITANCE BETWEEN GATE AND SOURCE/DRAIN;
CGD: CHANNEL CAPACITANCE BETWEEN GATE AND WELL REGION;
COV: CAPACITANCE OF OVERLAPPED REGION BETWEEN SHALLOW DOPED SOURCE REGION OR SHALLOW DOPED DRAIN REGION AND GATE STRUCTURE;
CIN: DEVICE INTERNAL CAPACITANCE, INCLUDING CGD, COV, AND JUNCTION CAPACITANCE;
L1, L2: CHANNEL LENGTH;
W1, W2: CHANNEL WIDTH;
a, b: respectively length of upper and lower parts of gate that exceed AA;
c, d: respectively length of upper and lower parts of M1 that exceed AA;
e: width of source/drain region leading-out line M1;
f: space between gate and edge of AA;
g: width of source/drain region leading-out line M2; width of gate leading-out line M1;
i: size of M1 that wraps CT, size of M2 that wraps V1;
h: size of AA that wraps CT.

A schematic diagram of the MOS structure in this embodiment of this application is as illustrated in FIG. 2, in which metal interconnect lines above M2 are omitted. The MOS structure is composed of a gate structure, a shallow doped source region and a shallow doped drain region composed of first conductive type lightly-doped regions, first conductive type heavily-doped source/drain regions, a second conductive type lightly-doped well region, a second conductive type heavily-doped region body leading-out layer, contact holes (CT), and metal interconnect lines.

(1) The shallow doped source region and the shallow doped drain region composed of the first conductive type lightly-doped regions are respectively formed on two sides of the gate, and extend to a position below a bottom of the gate. Capacitance Cov is formed between this part and the gate.

(2) The first conductive type heavily-doped source/drain regions are respectively formed on two sides of the gate and are wrapped in the second conductive type lightly-doped well region. Junction capacitance is formed between heavily-doped source/drain regions and lightly-doped well region of different conductive types. a conductive channel is formed on the surface of the second conductive type lightly-doped well region covered by the gate structure. Channel capacitance Cgd is formed between the gate and the lightly-doped well region.

(3) Sidewall capacitance Cf is formed between the gate structure and the first conductive type heavily-doped source/drain regions.

(4) Gate-to-contact capacitance Cco is formed between the gate structure and the CT;

(5) Capacitance Cgm is formed between the gate structure and the metal interconnect lines.

The gate structure related capacitance includes parasitic capacitance and device internal capacitance. The parasitic capacitance includes Cf, Cco, and Cgm. The device internal capacitance includes Cgd, Cov, and junction capacitance.

The method in this embodiment is as follows:

In step 1, a first test structure is designed. Specifically,

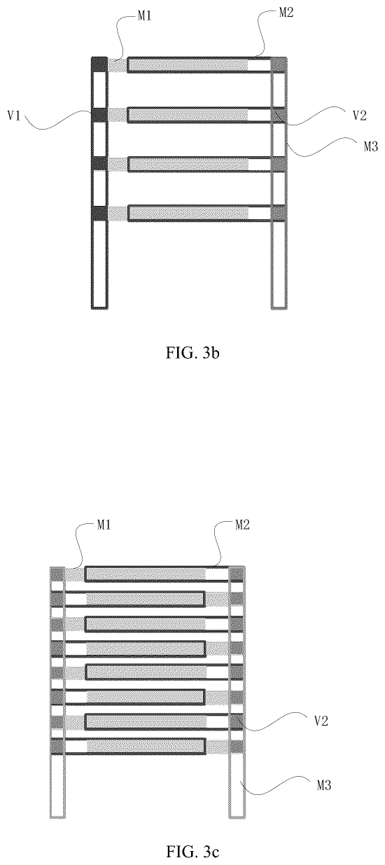

1. Intralayer capacitance test structures (as illustrated in FIG. 3a) with different widths and different spaces, an interlayer capacitance test structure (as illustrated in FIG. 3b) and an interlayer and intralayer test structure (as illustrated in FIG. 3c) of a first metal layer (i.e., first-layer metal lines) are designed. Actual capacitance values are respectively tested.

(1) The intralayer capacitance test structures (FIG. 3a) are used for testing sidewall capacitance between M1 and M1. The actual width and thickness of M1 influence the capacitance of this part.

(2) The interlayer capacitance test structure (FIG. 3b) is used for testing capacitance between M1 and M2. The actual width of M1 influence the capacitance of this part.

(3) The interlayer and intralayer test structure (FIG. 3c) is used for testing the sidewall capacitance between M1 and M1 and the interlayer capacitance between M1 and M2. The actual width and thickness of M1 influence the capacitance of this part.

2. A TEM is used for respectively measuring the actual width and thickness of the test structure. The following syntax is written into ITF:

(1) Table related to dimension of first metal layer in ITF: etch table

```
ETCH VS WIDTH AND SPACE {
  SPACE {S1 S2 S3 S4 ...}
  WIDTH {W1 W2 W3 W4 ...}
    {ETCHS1W1 ETCHS2W1 ETCHS3W1 ETCHS4W1 ...
      ETCHS1W2 ETCHS2W2 ETCHS3W2 ETCHS4W2 ...
      ETCHS1W3 ETCHS2W3 ETCHS3W3 ETCHS4W3 ...
      ETCHS1W4 ETCHS2W4 ETCHS3W4 ETCHS4W4 ...
      ...
      ...}
  }
```

(2) Table related to thickness of first
metal layer in ITF: thickness table

```
THICKNESS VS WIDTH AND SPACE {
SPACE {S1 S2 S3 S4 ...}
WIDTH {W1 W2 W3 W4 ...}
  {THICKS1W1 THICKS2W1 THICKS3W1 THICKS4W1 ...
    THICKS1W2 THICKS2W2 THICKS3W2 THICKS4W2 ...
    THICKS1W3 THICKS2W3 THICKS3W3 THICKS4W3 ...
    THICKS1W4 THICKS2W4 THICKS3W4 THICKS4W4 ...
    ...
    ...}
}
```

Note: S1 S2 S3 S4 . . . and W1 W2 W3 W4 . . . respectively are the spaces and widths of the layout of the first test structure. ETCHS1W1 is the width deviation value obtained from TEM slices in a case of width of W1 and space of S1. Other ETCHS2W1 and ETCHS3W1 represent the consistent meaning with ETCHS1W1. THICKS1W1 is the thickness deviation value obtained from TEM slices in a case of width of W1 and space of S1. Other THICKS2W1 and THICKS3W1 represent the consistent meaning with THICKS1W1.

3. StarRC simulation results of each test structure are compared with actual test results. The ETCH table (ETCHS1W1 . . . ) and the thickness table (THICKS1W1 . . . ) in ITF are adjusted to make the simulation results consistent with the actual test results.

This method calibrates the dimension and thickness tables of the first metal layer in the ITF file.

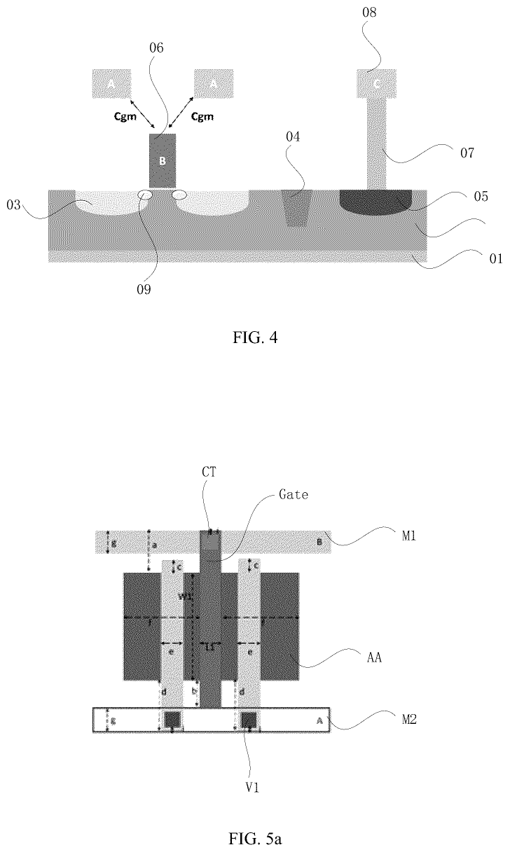

In step 2, a second test structure is designed. Contact holes in source/drain regions are removed from the MOS structure in FIG. 2, as illustrated in FIG. 4 which illustrates a schematic diagram of a sectional structure of a second test structure according to this application. PAD at end A is connected to zero potential, voltage is applied to PAD at end B (Gate) and current is tested, the same voltage as Gate is applied to PAD at end C (bulk), and the measured capacitance is Cgm.

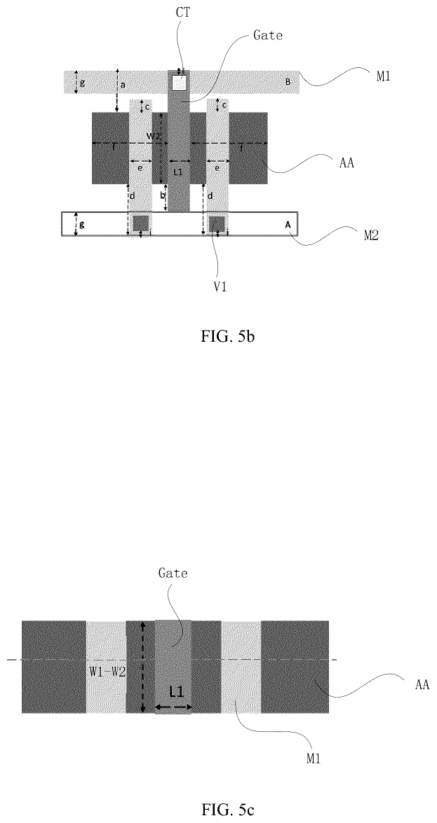

1. A second test structure including test structures with the same channel length, the same surrounding environment and different channel widths is designed, respectively as illustrated in FIG. 5a and FIG. 5b. Capacitance values Cgma and Cgmb thereof are respectively tested.

2. The same surrounding environment refers to that values of parameters a, b, c, d, e, f, g and i in FIG. 5a and FIG. 5b are all the same, so that the capacitance between Fgate/Gate and M1 on STI and the metal layer above M1 in the two figures is basically consistent. Therefore, Cgma-Cgmb can eliminate the influence of the parasitic capacitance of this part, and the capacitance is only related to the gate and M1, as illustrated in FIG. 5c.

3. In the layouts in FIG. 5a and FIG. 5b, the channel length is the same and L1, and the channel widths are different and respectively W1 and W2. Correspondingly, M1 lengths in the source/drain regions are respectively W1 and W2. It can be obtained that a difference between Cgma and Cgmb is caused by the change in the gate-to-M1 area, that is, in a case that the channel length is L1, the channel width is W1-W2 and the M1 length is W1-W2, Cgm1=Cgma-Cgmb.

4. The difference between the StarRC simulation results of the layouts corresponding to FIG. 5a and FIG. 5b is compared with the difference Cgm1 between the actual capacitance test results. Since the parameters (dimension and thickness) of M1 related to the parasitic capacitance have already been determined by the first test structure, the dimension and thickness values of Gate in ITF only need to be adjusted to make the simulation results consistent with the actual test results.

This method calibrates the dimension and thickness of Gate.

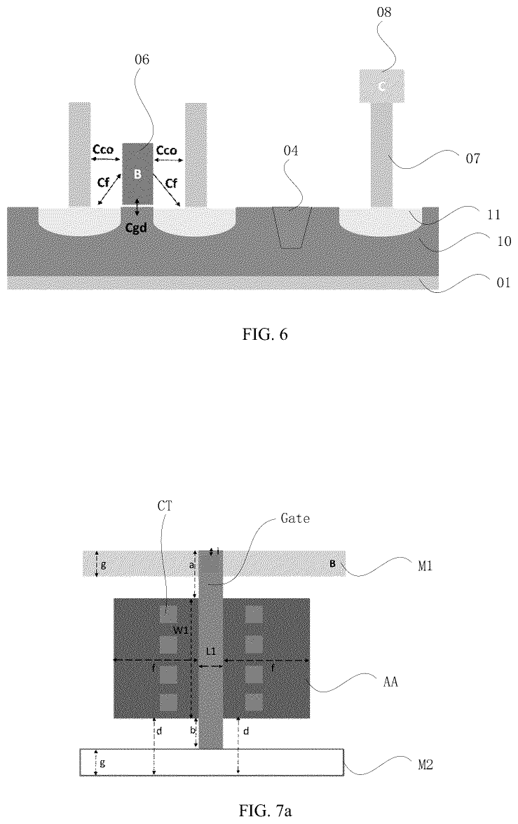

In step 3, a third test structure is designed. Metal interconnect lines in the source/drain regions are removed from the MOS structure in FIG. 2, the shallow doped source region and the shallow doped drain region composed of the first conductive type lightly-doped regions are removed, and the second type lightly-doped well region and the second type heavily-doped region body leading-out layer are respectively replaced with a first type lightly-doped well region 10 and a first type heavily-doped region body leading-out layer 11, so as to form a structure illustrated in FIG. 6. Voltage is applied to PAD at end B (Gate) and test the current, PAD at end C (bulk) is connected to zero potential, and the tested capacitance is C3a=Cf+Cco+Cgd.

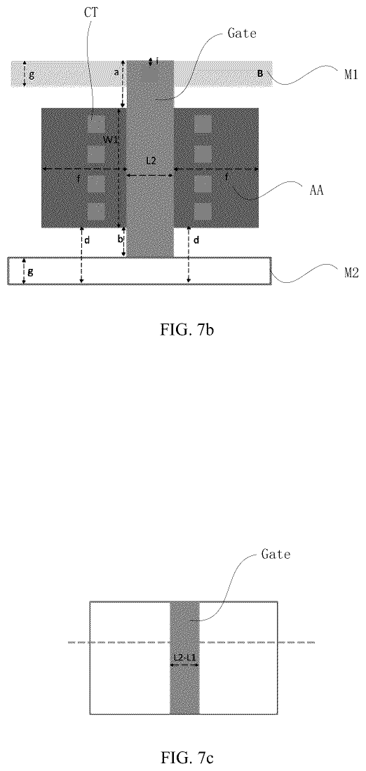

1. A third test structure including test structures with the same channel width, the same surrounding environment and different channel lengths is designed, respectively as illustrated in FIG. 7a and FIG. 7b. Capacitance values C3a1 and C3a2 thereof are respectively tested.

2. The same surrounding environment refers to that values of parameters a, b, c, d, e, f, g and i in FIG. 7a and FIG. 7b are all the same, so that the capacitance between Gate and CT and the source/drain regions in the two figures is basically consistent. Therefore, C3a2-C3a1 can eliminate the influence of the parasitic capacitance of this part, and the capacitance is only related to the gate and the first conductive type lightly-doped well region, as illustrated in FIG. 7c.

3. In the layouts in FIG. 7a and FIG. 7b, the channel width is the same and W1, and the channel widths are different and respectively L1 and L2. It can be obtained that a difference between C3a2 and C3a1 is caused by the change in the channel length, that is, in a case that the channel width is W1 and the channel length is L2-L1, Cgd=C3a2-C3a1.

4. The difference between the StarRC simulation results of the layouts corresponding to FIG. 7a and FIG. 7b is compared with the difference Cgd between the actual capacitance test results. If they are consistent, the dimension of Gate in ITF does not need to be adjusted; and if they are not consistent, the dimension of Gate in ITF needs to be adjusted to make the simulation results consistent with the actual test results. Then, the thickness of Gate in ITF is adjusted again to make the difference between the StarRC simulation results of the layouts corresponding to FIG. 7a and FIG. 7b consistent with the difference Cgm1 between the actual capacitance test results.

5. So far, the parameters related to Cgd in ITF are determined. Cco and Cf related parameters are respectively configured through the following steps.

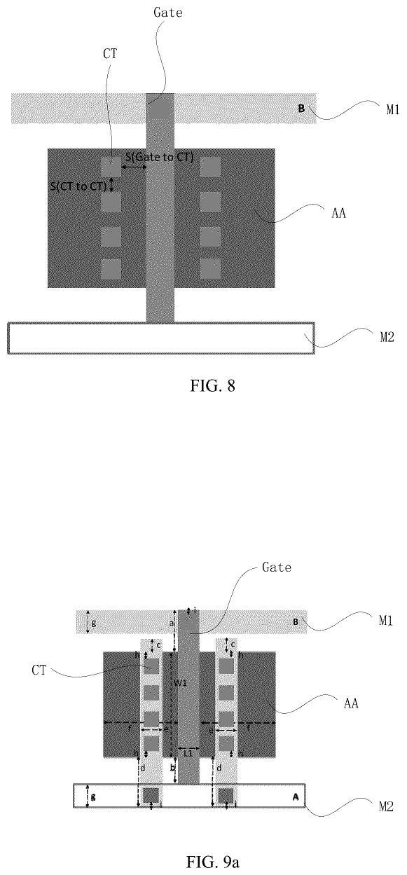

6. A third test structure including test structures with different spaces between CT: S (CT to CT)=Scc1 Scc2 Scc3 Scc4 . . . and different spaces between Gate and CT: S (Gate to CT)=Sgc1 Sgc2 Sgc3 Sgc4 . . . is designed, as illustrated in FIG. 8. The actual capacitance values thereof are respectively tested.

7. A TEM is used for respectively measuring CT dimension biases in a case of different spaces between CT and different spaces between Gate and CT of the third test structure, which are then written into the table of ITF, thus determining Cco related parameters in ITF.

Cco table:

```
Gate to CT VS CT space {
CT space { Scc1 Scc2 Scc3 Scc4 ...}
Gate to CT {Sgc1 Sgc2 Sgc3 Sgc4 ... }
CT bias { Sgc1Scc1 Sgc1Scc2 Sgc1Scc3 Sgc1Scc4
  Sgc2Scc1 Sgc2Scc2 Sgc2Scc3 Sgc2Scc4
  Sgc3Scc1 Sgc3Scc2 Sgc3Scc3 Sgc3Scc4
  Sgc4Scc1 Sgc4Scc2 Sgc4Scc3 Sgc4Scc4
}
}
```

Notes: Sgc1Scc1 is the bias of CT, from which the actual size of CT can be calculated. Sgc1Scc2 . . . has the consistent meaning with Sgc1Scc1.

Tables related to Cf and spaces between Gate and CT in ITF are set as follows. The StarRC simulation results of each test structure in FIG. 8 are compared with the actual test results, and the Cf table is adjusted to make the simulation results consistent with the actual test results.

Cf table:

CF VS Gate to CT space {
Gate to CT space{ Scc1 Scc2 Scc3 Scc4 ...}
CF VS Gate to CT space { Cf1 Cf2 Cf3 Cf4 ...}
}

Notes: Cf1 is the Cf capacitance value in a case that the Gate to CT space is Scc1. Cf2 Cf3 Cf4 . . . represent the consistent meaning with Cf1.

This method respectively calibrates the Cco and Cf related tables in the ITF file, so that the capacitance Cco and Cf in StarRC simulation is influenced by the spaces between CT and the spaces between Gate and CT, which complies with the actual situation.

In step 4, a fourth test structure is the MOS structure as illustrated in FIG. 2. PAD at end A (S/D) is connected to zero potential, voltage is applied to PAD at end B (Gate), current is tested, PAD at end C (bulk) is connected to zero potential, and the tested capacitance is Ctotal=Cf+Cco+Cgm+Cin.

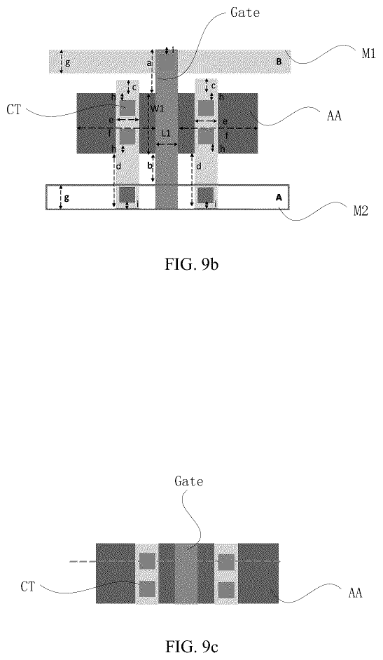

1. A fourth test structure including test structures with the same channel length, the same surrounding environment and different channel widths is designed, respectively as illustrated in FIG. 9a and FIG. 9b. Capacitance values Ctotal1 and Ctotal2 are respectively tested.

2. The same surrounding environment refers to that values of parameters a, b, c, d, e, f, g, h, i, j and k in FIG. 9a and FIG. 9b are all the same, so that the capacitance between Fgate/CT/M1 and AA/CT/M1 in the two figures is basically consistent. Therefore, Ctotal1-Ctotal2 can eliminate the influence of the parasitic capacitance of this part, and the capacitance around the channel is only obtained.

3. In the layouts in FIG. 9a and FIG. 9b, the channel length is the same and L1, and the channel widths are different and respectively W1 and W2. It can be obtained that a difference between Ctotal1 and Ctotal2 is caused by the change in the channel width, so it can be calculated that capacitance Ctotal_1=Ctotal1−Ctotal2−Cf+Cco+Cgm1+Cin in a case that the channel length is L1 and the channel width is W1-W2. The calculated capacitance value is not related to the metal interconnect lines above M1, as illustrated in FIG. 9c.

StarRC simulation and hspice simulation are respectively performed on the structures in FIG. 9a and FIG. 9b. Then, the simulation results are compared with the actual measurement results Ctotal_1 to check whether they are consistent. If they are not consistent, the model or the Cf table in ITF is adjusted.

This method ensures that the parasitic capacitance complies with the device internal capacitance involved in the model.

To sum up, the method according to this application can respectively calibrate the capacitance Cgm between and the gate and the metal interconnect lines, the capacitance Cco between the gate and the contact holes and the capacitance Cf between the gate and the source/drain regions, can make sure that the parasitic capacitance complies with the device internal capacitance involved in the model, and can effectively improve the accuracy of the parasitic capacitance extraction tool. Therefore, this application effectively overcomes various disadvantages in the existing technology and thus has a great industrial utilization value.

The above embodiments only exemplarily describe the principle and effect of this application, and are not intended to limit this application. Those skilled in the art may modify or change the above embodiments without departing from the spirit and scope of this application. Therefore, all equivalent modifications or changes made by those skilled in the art without departing from the spirit and technical concept disclosed in this application should still be covered by the claims of this application.

What is claimed is:

1. A test structure, at least comprising:
an MOS structure, the MOS structure comprising: a silicon substrate, a second conductive type lightly-doped well region located on the silicon substrate, and first conductive type heavily-doped source/drain regions, a shallow trench isolation region and a second conductive type heavily-doped body leading-out region sequentially spaced apart from each other and located on a shallow region of the second conductive type lightly-doped well region; a gate located on the second conductive type lightly-doped well region between the first conductive type heavily-doped source/drain regions; shallow doped source/drain regions composed of first conductive type lightly-doped regions, located in the second conductive type lightly-doped regions on two sides of the gate and overlapped with the first conductive type heavily-doped source/drain regions; contact holes connected respectively from the first conductive type heavily-doped source/drain regions and the second conductive type heavily-doped body leading-out region; and first metal lines located on the contact holes;
the gate related capacitance of the MOS structure comprising parasitic capacitance and device internal capacitance Cin; the parasitic capacitance comprising: capacitance Cf between the gate and source/drain regions, capacitance Cco between the gate and the contact holes, and capacitance Cgm1 between the gate and the first metal lines; the device internal capacitance Cin comprising: channel capacitance Cgd between the gate and a well region, capacitance Cov of overlapped regions respectively between the shallow doped source/drain regions and the gate structure, and junction capacitance between the first conductive type heavily-doped source/drain regions and the second conductive type lightly-doped well region;
a first test structure comprising a plurality of intralayer capacitance test structures, an interlayer capacitance test structure, and an interlayer and intralayer test structure,
each intralayer capacitance test structure of the plurality of intralayer capacitance test structures being composed of metal lines belonging to the same layer, the widths of the metal lines being the same, the spaces between adjacent metal lines being the same; the widths of the metal lines and the spaces between adjacent metal lines of the plurality of intralayer capacitance test structures being respectively different from each other, the metal lines of the plurality of intralayer capacitance test structures belonging to different layers, each intralayer capacitance test structure being used for measuring the capacitance between the metal lines of the same layer;
the interlayer capacitance test structure being composed of the intralayer capacitance test structures belonging to the different layers, and being used for measuring the capacitance between the metal lines of the different layers;
the interlayer and intralayer test structure being composed of the intralayer capacitance test structures and the interlayer capacitance test structure, and being used for measuring the total of the capacitance between the metal lines of the same layer and the capacitance between the metal lines of the different layers;
a second test structure formed by the MOS structure after removing the contact holes and used for measuring the capacitance Cgm1 between the gate and the first metal lines; the second test structure comprising different test structures with the same channel length, the same surrounding environment and different channel widths, and being used for calculating a difference in the capacitance Cgm1 between each other;
a third test structure formed by the MOS structure after removing the first metal lines on the first conductive type heavily-doped source/drain regions, removing the shallow doped source/drain regions composed of the first conductive type lightly-doped regions, and sequentially replacing the second conductive type lightly-doped well region and the second conductive type heavily-doped body leading-out region with a first conductive type lightly-doped well region and a first conductive type heavily-doped body leading-out region; the third test structure comprising different test structures with the same channel width, the same surrounding environment and different channel lengths, and being used for measuring a difference in the channel capacitance Cgd between each other; the third test structure further comprising different test structures with different spaces between the contact holes and different spaces between the contact holes and the gate; and
a fourth test structure formed by the MOS structure, the fourth test structure comprising different test structures with the same channel length, the same surrounding environment and different channel widths, and being used for measuring the total difference Ctotal in the capacitance Cf between the gate and the source/drain regions, the capacitance Cco between the gate and the contact holes, the capacitance Cgm1 between the gate and the first metal lines, and the device internal capacitance Cin.

2. The test structure according to claim 1, wherein the MOS structure is an N-type device, the first conductive type is N-type, and the second conductive type is P-type.

3. The test structure according to claim 1, wherein the MOS structure is a P-type device, the first conductive type is P-type, and the second conductive type is N-type.

4. The test structure according to claim 1, wherein the capacitance of the third test structure is the total of the capacitance Cf between the gate and the source/drain regions, the capacitance Cco between the gate and the contact holes, and the channel capacitance Cgd between the gate and the well region.

5. A method for calibrating parasitic capacitance, at least comprising:
step 1: providing a first test structure, the first test structure comprising a plurality of intralayer capacitance test structures, an interlayer capacitance test structure, and an interlayer and intralayer test structure,
each intralayer capacitance test structure of the plurality of intralayer capacitance test structures being composed of metal lines belonging to the same layer, the widths of the metal lines being the same, the spaces between adjacent metal lines being the same; the widths of the metal lines and the spaces between adjacent metal lines of the plurality of intralayer capacitance test structures being respectively different from each other, the metal lines of the plurality of intralayer capacitance test structures belonging to different layers;
the interlayer capacitance test structure being composed of the intralayer capacitance test structures belonging to the different layers;
the interlayer and intralayer test structure being composed of the intralayer capacitance test structures and the interlayer capacitance test structure;
respectively measuring the capacitance between the metal lines of the same layer in the intralayer capacitance test structures, the capacitance between the metal lines of the different layers in the interlayer capacitance test structure, and the total of the capacitance between the metal lines of the same layer and the capacitance between the metal lines of the different layers in the interlayer and intralayer test structure, measurement results of the capacitance and the total of the capacitance being actual capacitance values;
respectively measuring the actual widths and thicknesses of the metal lines and the spaces between adjacent metal lines in the first test structure, and writing measurement values into an ITF file, the ITF file being an input file of a backend parasitic capacitance and resistance extraction tool;
comparing the actual capacitance values with respective simulation values, and adjusting numerical values in an ETCH table and a thickness table in the ITF file to make simulation results consistent with actual measurement results;
step 2: providing an MOS structure, the MOS structure comprising: a silicon substrate, a second conductive type lightly-doped well region located on the silicon substrate, and first conductive type heavily-doped source/drain regions, a shallow trench isolation region and a second conductive type heavily-doped body leading-out region sequentially spaced apart from each other and located on a shallow region of the second conductive type lightly-doped well region; a gate located on the second conductive type lightly-doped well region between the first conductive type heavily-doped source/drain regions; shallow doped source/drain regions composed of first conductive type lightly-doped regions, located in the second conductive type lightly-doped regions on two sides of the gate and overlapped with the first conductive type heavily-doped source/drain regions; contact holes connected respectively from the first conductive type heavily-doped source/drain regions and the second conductive type heavily-doped body leading-out region; and first metal lines located on the contact holes;
the gate related capacitance of the MOS structure comprising parasitic capacitance and device internal capacitance Cin; the parasitic capacitance comprising: capacitance Cf between the gate and source/drain regions, capacitance Cco between the gate and the contact holes, and capacitance Cgm1 between the gate and the first metal lines; the device internal capacitance Cin comprising: channel capacitance Cgd between the gate and a well region, capacitance Cov of overlapped regions respectively between the shallow doped source/drain regions and the gate structure, and junction capacitance between the first conductive type heavily-doped source/drain regions and the second conductive type lightly-doped well region;
providing a second test structure, the second test structure being formed by the MOS structure after removing the contact holes; the second test structure comprising different test structures with the same channel length, the same surrounding environment and different channel widths; measuring the capacitance Cgm1 between the gate and the first metal lines of the different test structures, and calculating a difference in the capacitance Cgm1 between each other;
performing simulation on the capacitance Cgm1 between the gate and the first metal lines of the different test structures by using the backend parasitic capacitance and resistance extraction tool to obtain simulation values, and calculating a difference in the simulation capacitance Cgm1 between the different test structures;
comparing the difference in the simulation capacitance Cgm1 with the measured difference in the capacitance Cgm1 between the different test structures, and adjusting the dimension of the gate in the ITF file to make simulation results consistent with actual measurement results;
step 3: providing a third test structure, the third test structure being formed by the MOS structure after removing the first metal lines on the first conductive type heavily-doped source/drain regions, removing the shallow doped source/drain regions composed of the first conductive type lightly-doped regions, and sequentially replacing the second conductive type lightly-doped well region and the second conductive type heavily-doped body leading-out region with a first conductive type lightly-doped well region and a first conductive type heavily-doped body leading-out region; the third test structure comprising different test structures with the same channel width, the same surrounding environment and different channel lengths; measuring the channel capacitance Cgd of the different test structures, and calculating a difference in the capacitance Cgd between each other;
performing simulation on the channel capacitance Cgd of the different test structures by using the backend parasitic capacitance and resistance extraction tool to obtain simulation values, and calculating a difference in the simulation capacitance Cgd between the different test structures;
comparing the difference in the simulation capacitance Cgd with the measured difference in the capacitance Cgd between the different test structures, and adjusting the dimension of the gate in the ITF file to make simulation results consistent with actual measurement results;
the third test structure further comprising different test structures with different spaces between the contact holes and different spaces between the contact holes and the gate; measuring capacitance values of the different test structures; determining capacitance Cco related parameters in the ITF file, and then calibrating a capacitance Cf table in the ITF file according to the actually measured capacitance values;
step 4: providing a fourth test structure, the fourth test structure being formed by the MOS structure, the fourth test structure comprising different test structures with the same channel length, the same surrounding environment and different channel widths; measuring the capacitance Cf between the gate and the source/drain regions, the capacitance Cco between the gate and the contact holes, and the capacitance Cgm1 between the gate and the first metal lines of the different test structures, and the device internal capacitance Cin, and calculating the total difference Ctotal in the capacitance; and
performing simulation on the total difference Ctotal in the capacitance of the different test structures by using the backend parasitic capacitance and resistance extraction tool to obtain simulation values, and comparing the simulation values with actual measurement values to adjust the Cf table in the ITF file.

6. The method for calibrating parasitic capacitance according to claim 5, wherein in step 1, an electron transmission microscope is used for respectively measuring the widths of and spaces between the metal lines, and a WAT is used for measuring the capacitance between the metal lines of the same layer in the intralayer capacitance test structures, the capacitance between the metal lines of the different layers in the interlayer capacitance test structure, and the total of the capacitance between the metal lines of the same layer and the capacitance between the metal lines of the different layers in the interlayer and intralayer test structure.

7. The method for calibrating parasitic capacitance according to claim 5, wherein in step 1 to step 4, the backend parasitic capacitance and resistance extraction tool is StarRC.

8. The method for calibrating parasitic capacitance according to claim 5, wherein in step 2, a WAT is used for respectively measuring the capacitance Cgm1 between the gate and the first metal lines of the different test structures.

9. The method for calibrating parasitic capacitance according to claim 5, wherein in step 3, a WAT is used for respectively measuring the channel capacitance Cgd of the different test structures.

10. The method for calibrating parasitic capacitance according to claim 5, wherein in step 4, a WAT is used for respectively measuring the capacitance Cf between the gate and the source/drain regions, the capacitance Cco between the gate and the contact holes and the capacitance Cgm1 between the gate and the first metal lines of the different test structures, and the device internal capacitance Cin.
